(19) United States
(12) Patent Application Publication
(10) Pub. No.: US 2024/0379397 A1
(43) Pub. Date: Nov. 14, 2024

(54) SUBSTRATE TRANSFER APPARATUS

(71) Applicant: VM Inc., Icheon-si (KR)

(72) Inventors: Sang Woo Lee, Suwon-si (KR); Woo Hyung Choi, Seongnam-si (KR)

(73) Assignee: VM Inc., Icheon-si (KR)

(21) Appl. No.: 18/660,164

(22) Filed: May 9, 2024

(30) Foreign Application Priority Data
May 12, 2023 (KR) 10-2023-0061498

(51) Int. Cl. H01L 21/677

(52) U.S. Cl. CPC H01L 21/67742; H01L 21/67745

(57) ABSTRACT

A substrate transfer apparatus includes a moving plate, a load lock chamber disposed at one end of the moving plate, a plurality of processing chambers disposed in a longitudinal direction at opposite ends of the moving plate, and an arm that is connected with the moving plate and that transfers a substrate between one processing chamber among the plurality of processing chambers and the load lock chamber. The moving plate provides a first path along which a first pivot axis of the arm linearly moves in a lateral direction on the moving plate.

### CROSS-REFERENCE TO RELATED APPLICATIONS

A claim for priority under 35 U.S.C. § 119 is made to Korean Patent Application No. 10-2023-0061498 filed on May 12, 2023, in the Korean Intellectual Property Office, the entire contents of which are hereby incorporated by reference.

### BACKGROUND

Embodiments of the inventive concept described herein relate to a substrate transfer apparatus.

Throughput in equipment used for a semiconductor or display process refers to the number of wafers or substrates processed per unit time in a single process. The throughput may be determined based on process time of a processing chamber, an intake/exhaust speed of a vacuum robot, cooling/heating time of a wafer, and the like. However, there is a limit to maximize the throughput of the equipment only with these factors.

### SUMMARY

Embodiments of the inventive concept provide a substrate transfer apparatus for minimizing a lateral width by enabling an axis of a robot arm to move in a lateral direction.

According to an exemplary embodiment, a substrate transfer apparatus includes a moving plate, a load lock chamber disposed at one end of the moving plate, a plurality of processing chambers disposed in a longitudinal direction at opposite ends of the moving plate, and an arm that is connected with the moving plate and that transfers a substrate between one processing chamber among the plurality of processing chambers and the load lock chamber. The moving plate provides a first path along which a first pivot axis of the arm linearly moves in a lateral direction on the moving plate.

According to an embodiment, a position of the first pivot axis on the first path may be determined based on a position of the one processing chamber relative to the moving plate.

According to an embodiment, the moving plate may provide a second path along which the first pivot axis linearly moves in the longitudinal direction on the moving plate.

According to an embodiment, the second path may cross the first path.

According to an embodiment, the moving plate may provide a third path along which the first pivot axis linearly moves in an oblique direction on the moving plate.

According to an embodiment, the third path may cross the first path.

According to an embodiment, the first path may include a rail.

According to an embodiment, the first path may include a plurality of links, and the first pivot axis may be disposed at one of the plurality of links to transfer the substrate from the one processing chamber.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIGS. 1A to 1C are plan views illustrating different operations of a substrate transfer apparatus according to an embodiment of the inventive concept;

FIG. 2 is a plan view of a substrate transfer apparatus configured to enable a linear motion in four directions according to an embodiment of the inventive concept;

FIG. 3 is a plan view of a substrate transfer apparatus configured to enable an oblique motion according to an embodiment of the inventive concept; and

FIGS. 4A and 4B are plan views of arm units including different members according to an embodiment of the inventive concept.

### DETAILED DESCRIPTION

Hereinafter, specific details for carrying out the inventive concept will be described in detail with reference to the accompanying drawings. However, detailed descriptions related to well-known functions or configurations will be omitted when they may make subject matters of the inventive concept unnecessarily obscure.

In the accompanying drawings, identical or corresponding components will be assigned with identical reference numerals. Furthermore, in the following description of embodiments, repetitive descriptions of the identical or corresponding components may be omitted. However, the omission of the descriptions of the components does not intend that the components are not included in certain embodiments.

Aspects, features, and advantages of the inventive concept will become apparent from the following description of embodiments given in conjunction with the accompanying drawings. However, the inventive concept is not limited to the embodiments disclosed herein and may be implemented in various different forms. Herein, the embodiments are provided to provide complete disclosure of the inventive concept and to provide thorough understanding of the inventive concept to those skilled in the art.

The terminology used herein will be described briefly, and the inventive concept will be described in detail. The terminology used herein is defined in consideration of the function of corresponding components used in the inventive concept and may be varied according to users, operator's intention, or practices. In addition, an arbitrary defined terminology may be used in a specific case and will be described in detail in a corresponding description paragraph. Therefore, the terminology used herein is for the purpose of describing particular embodiments only and is not intended to be limiting of the inventive concept.

The terms of a singular form may include plural forms unless otherwise specified. In addition, the terms of a plural form may include singular forms unless otherwise specified. In this specification, when a portion “includes” a component, it may mean that the portion does not exclude another component unless specifically described to the contrary, but may further include another component.

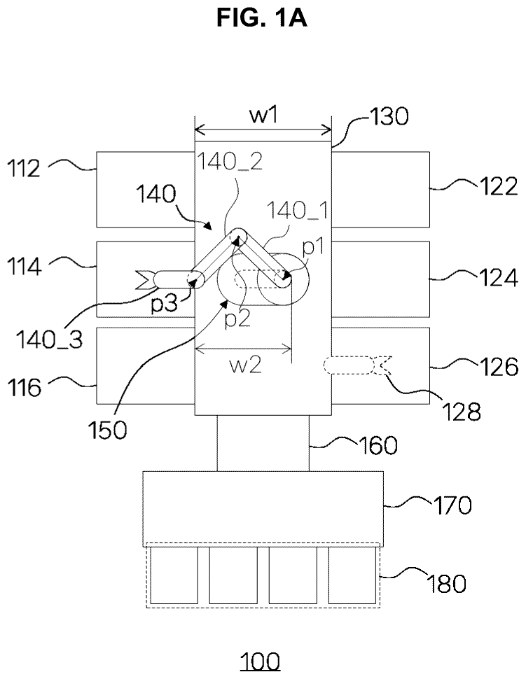

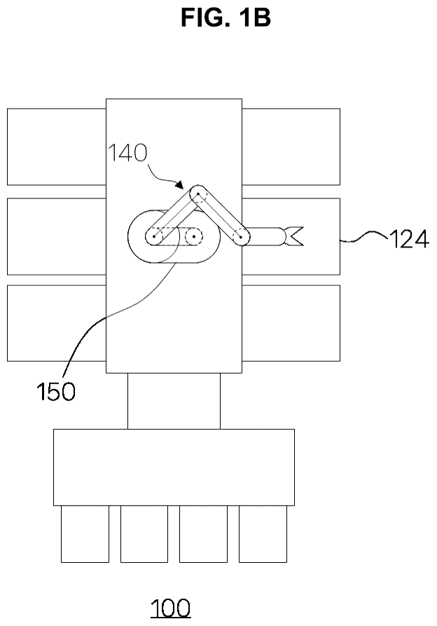

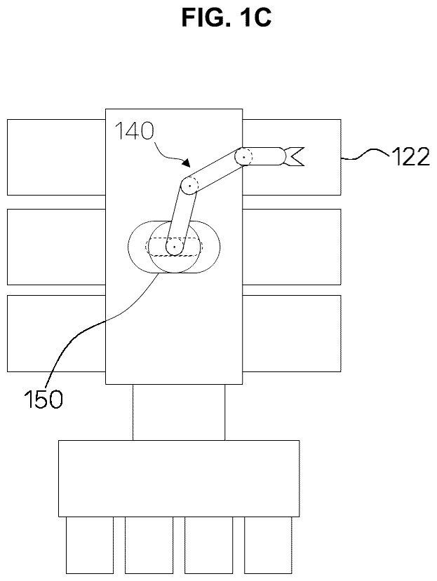

FIGS. 1A to 1C are plan views illustrating different operations of a substrate transfer apparatus 100 according to an embodiment of the inventive concept. As illustrated, the substrate transfer apparatus 100 may include at least one of a plurality of processing chambers 112 to 126, a moving plate 130, an arm 140, a load lock chamber 160, an equipment front end module (EFEM) 170, and a plurality of load port modules (LPMs) 180.

The arm 140 may transfer a substrate (e.g., a wafer) obtained from one LPM among the plurality of LPMs 180 to one target processing chamber (here, the second processing chamber 114) among the plurality of processing chambers 112 to 126 through the load lock chamber 160. In addition, the arm 140 may transfer the substrate processed in the target processing chamber among the plurality of processing chambers 112 to 126 to any one LPM through the load lock chamber 160. Meanwhile, a “target processing chamber” used herein may refer to a processing chamber into which a substrate is loaded by the arm 140 and from which the substrate is unloaded by the arm 140.

A plurality of substrate transfer apparatuses 100 may be provided in a limited space. Accordingly, to improve substrate throughput by the substrate transfer apparatus 100, it may be necessary to reduce the width w of the moving plate 130 that determines the footprint of the substrate transfer apparatus 100. Hereinafter, components of the substrate transfer apparatus 100 configured to minimize the width w of the moving plate 130 in consideration of movement of the arm 140 will be described in detail with reference to FIG. 1A.

The plurality of processing chambers 112 to 126 may be disposed at the periphery of the moving plate 130. Specifically, the plurality of processing chambers 112 to 126 may be disposed in the longitudinal direction at opposite edges (that is, opposite ends) of the moving plate 130. For example, the first set of processing chambers 112 to 116 may be disposed in the longitudinal direction at one edge (a left edge in FIG. 1A) of the moving plate 130. In another example, the second set of processing chambers 122 to 126 may be disposed in the longitudinal direction at an opposite edge (a right edge in FIG. 1A) of the moving plate 130.

The load lock chamber 160 may be disposed at one end of the moving plate 130. Specifically, as illustrated in FIG. 1A, the load lock chamber 160 may be disposed at a lower edge (that is, a lower end) of the moving plate 130. Meanwhile, although one load lock chamber 160 is illustrated in FIG. 1A, the inventive concept is not limited thereto. For example, the substrate transfer apparatus 100 may include two or more load lock chambers. In this case, a substrate to be transferred to any one processing chamber may be disposed in one load lock chamber. In addition, a substrate obtained from any one processing chamber may be disposed in another load lock chamber.

Referring to FIG. 1A, as described above, the arm 140 may transfer a substrate between the target processing chamber (here, the second processing chamber 114) among the plurality of processing chambers 112 to 126 and the load lock chamber 160. In this case, the substrate has to be loaded and unloaded at a certain position in the target processing chamber. To this end, at least a portion (here, a third region 140_3) of the arm 140 may stop at a predetermined position on the target processing chamber when the arm 140 loads/unloads the substrate. For example, when the arm 140 loads a substrate into the sixth processing chamber 126 or unloads the substrate from the sixth processing chamber 126, at least a portion of the arm 140 may stop at a specific position 128 on the sixth processing chamber 126.

The arm 140 may include one or more joints. Accordingly, the arm 140 may include a plurality of regions 140_1 to 140_3 distinguished from one another based on the joints. For example, the arm 140 may include the first region 140_1 connected with the moving plate 130 through a joint and the third region 140_3 in which a substrate is accommodated. Additionally, the arm 140 may include the second region 140_2 disposed between the first region 140_1 and the third region 140_3 and connected, at opposite ends, with the first region 140_1 and the third region 140_3 through joints.

The joints of the arm 140 may include pivot axes, respectively. Accordingly, the plurality of regions 140_1 to 140_3 of the arm 140 may pivot around the pivot axes, respectively. For example, the first region 140_1 may pivot around a first pivot axis p1 relative to the moving plate 130. In another example, the first region 140_1 and/or the second region 140_2 may pivot around a second pivot axis p2. In another example, the second region 140_2 and/or the third region 140_3 may pivot around a third pivot axis p3.

Referring to FIGS. 1A to 1C, the arm 140 may move along a path 150 provided by the moving plate 130. Specifically, the arm 140 may linearly move along the path 150 on the moving plate 130 in the lateral direction. In this case, the position of the first pivot axis p1 on the path 150 may be determined based on the target processing chamber. For example, when the target processing chamber is the second processing chamber 114 as in FIG. 1A, the first pivot axis p1 on the path 150 may be located at a right end of the path 150. In another example, when the target processing chamber is the fifth processing chamber 124 as in FIG. 1B, the first pivot axis p1 on the path 150 may be located at a left end of the path 150. In another example, when the target processing chamber is the sixth processing chamber 126, the first pivot axis p1 on the path 150 may be located at the center of the path 150.

Depending on the above-described configuration and operation of the arm 140, the third region 140_3 of the arm 140 may stop at the predetermined position on the second processing chamber 114, which is the target processing chamber, to load and unload the substrate. In this case, the lateral width w1 of the moving plate 130 may be greater than the lateral width w2 of the area occupied by the arm 140 on the moving plate 130. In addition, twice the lateral width w2 of the area occupied by the arm 140 on the moving plate 130 may be greater than the lateral width w1 of the moving plate 130. The lateral width w2 of the area occupied by the arm 140 on the moving plate 130 may be a minimum value determined based on a range of motion of the arm 140. The lateral width w1 of the moving plate 130 may also be minimized by the above-described configuration, and thus a large number of substrate transfer apparatuses 100 may be disposed in a limited space.

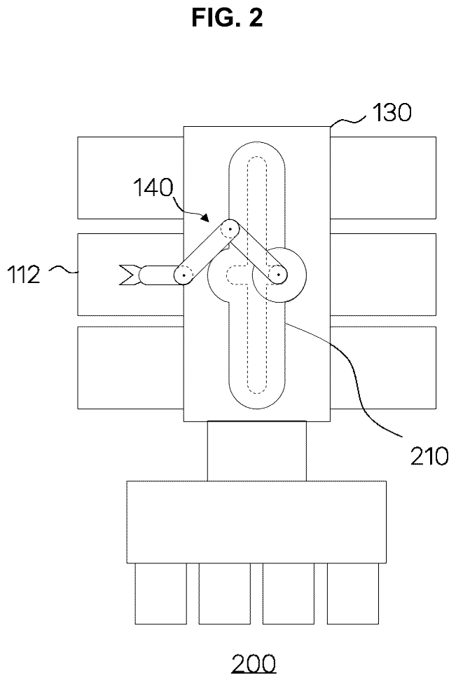

FIG. 2 is a plan view of a substrate transfer apparatus 200 configured to enable a linear motion in four directions according to an embodiment of the inventive concept. Here, the substrate transfer apparatus 200 may correspond to the substrate transfer apparatus 100 of FIGS. 1A to 1C. That is, the substrate transfer apparatus 200 may include at least one of the plurality of processing chambers 112 to 126, the moving plate 130, the arm 140, the load lock chamber 160, the equipment front end module (EFEM) 170, and the plurality of load port modules (LPMs) 180. Additionally, the moving plate 130 of the substrate transfer apparatus 200 may further include a path 210 along which the arm 140 moves relative to the moving plate 130 in the lateral direction and the longitudinal direction.

Meanwhile, although FIG. 2 illustrates an example that one lateral path and one longitudinal path of the path 210 cross each other at one point, the inventive concept is not limited thereto. For example, the substrate transfer apparatus 200 may include a lateral path and a longitudinal path independently disposed without crossing each other. In this case, arms may be disposed on the lateral path and the longitudinal path, respectively. Alternatively, the substrate transfer apparatus 200 may include two or more lateral paths and/or two or more longitudinal paths.

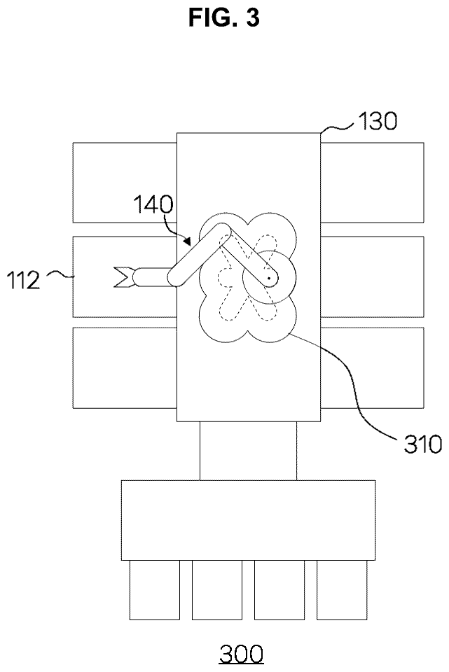

FIG. 3 is a plan view of a substrate transfer apparatus 300 configured to enable an oblique motion according to an embodiment of the inventive concept. Here, the substrate transfer apparatus 300 may correspond to the substrate transfer apparatus 100 of FIGS. 1A to 1C. That is, the substrate transfer apparatus 300 may include at least one of the plurality of processing chambers 112 to 126, the moving plate 130, the arm 140, the load lock chamber 160, the equipment front end module (EFEM) 170, and the plurality of load port modules (LPMs) 180. Additionally, the moving plate 130 of the substrate transfer apparatus 300 may further include a path 310 along which the arm 140 performs an oblique motion relative to the moving plate 130.

Meanwhile, although FIG. 3 illustrates an example that one lateral path and two oblique paths of the path 310 cross one another at one point, the inventive concept is not limited thereto. For example, the substrate transfer apparatus 300 may include a lateral path and an oblique path independently disposed without crossing each other. In this case, arms may be disposed on the lateral path and the oblique path, respectively. Alternatively, the substrate transfer apparatus 300 may include one, three or more oblique paths.

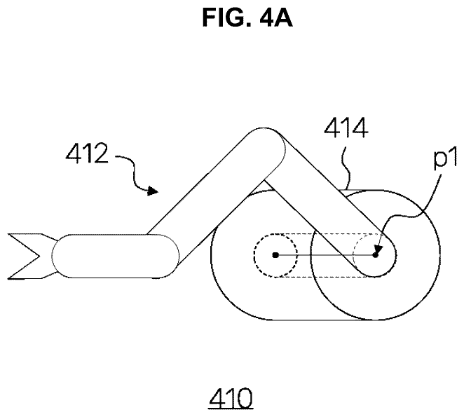

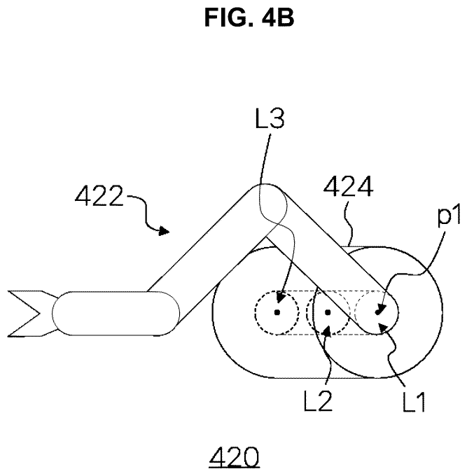

FIGS. 4A and 4B are plan views of arm units 410 and 420 including different members according to an embodiment of the inventive concept. Here, arms 412 and 422 and paths 414 and 424 of FIGS. 4A and 4B may correspond to the arms and the paths illustrated in FIGS. 1A to 3. That is, the arms illustrated in FIGS. 1A to 3 may be replaced with at least one of the arms 412 and 422 of FIG. 4. In addition, the paths illustrated in FIGS. 1A to 3 may be replaced with at least one of the paths 414 and 424 of FIG. 4.

FIG. 4A illustrates an example that the path 414 includes a rail. In this case, a first pivot axis p1 of the arm 412 may be disposed at any point along the rail included in the path 414.

In contrast, FIG. 4B illustrates an example that the path 424 includes a plurality of links L1 to L3. In this case, a first pivot axis p1 of the arm 422 may be disposed at any one of the plurality of links L1 to L3 included in the path 424.

According to the embodiments of the inventive concept, substrate throughputs in limited spaces may be maximized by reducing the footprints of the substrate transfer apparatuses.

Various modifications of the inventive concept will be obvious to those skilled in the art, and the general principles defined herein may be applied to various modifications without departing from the spirit or scope of the inventive concept. Accordingly, the inventive concept is not intended to be limited to the examples set forth herein but is intended to be accorded the widest scope consistent with the principles and novel features disclosed herein.

Although example implementations may refer to utilizing aspects of the presently disclosed subject matter in the context of one or more standalone computer systems, the subject matter is not so limited, and they may be implemented in conjunction with any computing environment, such as a network or distributed computing environment. Furthermore, aspects of the presently disclosed subject matter may be implemented in or across a plurality of processing chips or devices, and storage may be similarly influenced across a plurality of devices. Such devices may include PCs, network servers, and handheld devices.

While the inventive concept has been described with reference to exemplary embodiments, it will be apparent to those skilled in the art that various changes and modifications may be made without departing from the spirit and scope of the inventive concept. Therefore, it should be understood that the above embodiments are not limiting, but illustrative.

What is claimed is:

1. A substrate transfer apparatus comprising:
a moving plate;
a load lock chamber disposed at one end of the moving plate;
a plurality of processing chambers disposed in a longitudinal direction at both ends of the moving plate; and
an arm connected with the moving plate and configured to transfer a substrate between one processing chamber among the plurality of processing chambers and the load lock chamber,
wherein the moving plate provides a first path along which a first pivot axis of the arm linearly moves in a lateral direction on the moving plate.

2. The substrate transfer apparatus of claim 1, wherein a position of the first pivot axis on the first path is determined based on a position of the one processing chamber relative to the moving plate.

3. The substrate transfer apparatus of claim 1, wherein the moving plate provides a second path along which the first pivot axis linearly moves in the longitudinal direction on the moving plate.

4. The substrate transfer apparatus of claim 3, wherein the second path crosses the first path.

5. The substrate transfer apparatus of claim 1, wherein the moving plate provides a third path along which the first pivot axis linearly moves in an oblique direction on the moving plate.

6. The substrate transfer apparatus of claim 5, wherein the third path crosses the first path.

7. The substrate transfer apparatus of claim 1, wherein the first path includes a rail.

8. The substrate transfer apparatus of claim 1, wherein the first path includes a plurality of links, and the first pivot axis is disposed at one of the plurality of links to transfer the substrate from the one processing chamber.
